(19) United States
(12) Patent Application Publication
(10) Pub. No.: US 2009/0160044 A1
(43) Pub. Date: Jun. 25, 2009

(54) SEMICONDUCTOR MODULE MOUNTING STRUCTURE

(75) Inventors: Makoto Taniguchi, Oobu-shi (JP); Hideki Kabune, Nagoya (JP); Katsunori Tanaka, Ichinomiya-shi (JP); Yukari Tanaka, Ichinomiya-shi (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city (JP)

(21) Appl. No.: 12/343,597

(22) Filed: Dec. 24, 2008

(30) Foreign Application Priority Data
Dec. 24, 2007 (JP) 2007-331241

(51) Int. Cl. H01L 23/04; H01L 23/48; H01L 23/34; H01L 23/14

(52) U.S. Cl. 257/690; 257/698; 257/707; 257/E23.008; 257/E23.191; 257/E23.08

(57) ABSTRACT

The semiconductor module mounting structure includes a semiconductor module including therein a semiconductor device and electrodes exposed to both surfaces thereof, a wiring substrate having a mounting surface on which the semiconductor module is mounted, and a heat radiating body for dissipating heat from the semiconductor module. The wiring substrate is formed with a ground wiring such that at least a part of the ground wiring is exposed to a back surface thereof opposite to the mounting surface. The exposed surface of the ground wiring exposed to the back surface is in thermal contact with the heat radiating body. At least one of the electrodes exposed to one of the both surfaces opposed to the wiring substrate is in electrical contact with the ground wiring through a through hole formed in the wiring substrate.

### CROSS-REFERENCE TO RELATED APPLICATION

This application is related to Japanese Patent Application No. 2007-331241 filed on Dec. 24, 2007, the contents of which are hereby incorporated by reference.

### BACKGROUND OF THE INVENTION

1. Field of the Invention

The present invention relates to a semiconductor module mounting structure in which a semiconductor module including therein a semiconductor device and having electrodes exposed to both surfaces in the thickness direction thereof is mounted on a wiring substrate.

2. Description of Related Art

It is known to use, as switching elements of a power conversion device such as an inverter, semiconductor devices such as MOSFETs. Such a semiconductor device may be mounted on the power conversion device in the form of a semiconductor module having a structure in which electrodes located at one surface of the semiconductor module are solder-joined to a heat radiating plate, and the semiconductor device is encapsulated by a resin material covering the other surface together with its terminals. For example, refer to “To Measure Silicon Chip Temperature of MOSFET” by Jun Honda/Jorge Cerezo in the December 2007 issue of Transistor Technology, p. 165, FIG. 1, published by CQ Publishing Co., Ltd. The heat radiating plate is closely secured to a heat radiating member through a heat-conductive adhesive to dissipate heat from the semiconductor device.

However, since the surface on the side opposite to the heat radiating plate is covered by the resin material, it is difficult to dissipate heat through this surface. To solve this problem, a new semiconductor module in which the electrodes are exposed to both surfaces thereof to enable dissipating heat through the both surfaces is under development. For details refer to p. 165-167 of the above referred magazine.

Also in the new semiconductor module, to mount on a wiring substrate, the electrodes exposed to one of the surfaces thereof have to be connected to wiring patterns formed on the wiring substrate, the wiring patterns being located on the side of the semiconductor module and having a very large thickness. Accordingly, it is difficult to sufficiently dissipate heat transmitted to the wiring patterns from the electrodes located at the one surface of the semiconductor module opposed to the wiring substrate. Hence, even the new semiconductor module cannot sufficiently dissipate heat from both surfaces thereof.

### SUMMARY OF THE INVENTION

The present invention provides a semiconductor module mounting structure, comprising:

a semiconductor module including therein a semiconductor device and electrodes exposed to both surfaces thereof in a thickness direction thereof;

a wiring substrate having a mounting surface on which the semiconductor module is mounted; and

a first heat radiating body for dissipating heat from the semiconductor module;

the wiring substrate being formed with a ground wiring such that at least a part of the ground wiring is exposed to a back surface thereof opposite to the mounting surface;

an exposed surface of the ground wiring exposed to the back surface being in thermal contact with the first heat radiating body,

at least one of the electrodes exposed to one of the both surfaces as an opposed surface opposed to the wiring substrate being in electrical contact with the ground wiring through a through hole formed in the wiring substrate.

According to the present invention, there is provided a semiconductor module mounting structure capable of dissipating heat from both surfaces of a semiconductor module included therein.

Other advantages and features of the invention will become apparent from the following description including the drawings and claims.

### BRIEF DESCRIPTION OF THE DRAWINGS

In the accompanying drawings:

FIG. 1 is a partial cross-sectional view of a semiconductor module mounting structure of a first embodiment of the invention;

FIG. 2 is a perspective view of a semiconductor module included in the semiconductor module mounting structure of the first embodiment;

FIG. 3 is a plan view of the semiconductor module as viewed from the side of the opposed surface thereof;

FIG. 4 is a cross-sectional view of FIG. 3 taken along the line A-A;

FIG. 5 is a plan view of a mounting surface of a wiring substrate of the semiconductor module mounting structure of the first embodiment;

FIGS. 6A and 6B are diagrams for explaining a method of forming the wiring substrate of the semiconductor module mounting structure of the first embodiment;

FIG. 7 is a circuit diagram of a motor drive circuit for driving a brushless motor including an inverter which uses the semiconductor module mounting structure of the first embodiment;

FIG. 8 is a partial cross-sectional view of a semiconductor module mounting structure of a second embodiment of the invention;

FIG. 9 is a plan view of a mounting surface of a wiring substrate of the semiconductor module mounting structure of the second embodiment;

FIG. 10 is a partial cross-sectional view of a semiconductor module mounting structure of a third embodiment of the invention;

FIG. 11 is a partial cross-sectional view of a semiconductor module mounting structure of a fourth embodiment of the invention;

FIG. 12 is a partial cross-sectional view of a semiconductor module mounting structure of a fifth embodiment of the invention;

FIG. 13 is a partial cross-sectional view of a semiconductor module mounting structure of a sixth embodiment of the invention;

FIG. 14 is a circuit diagram of a motor drive circuit for driving a brushless motor including an inverter which uses a semiconductor module mounting structure of a seventh embodiment of the invention; and

FIG. 15 is a circuit diagram of a motor drive circuit for driving a brushless motor including an inverter which uses a semiconductor module mounting structure of an eighth embodiment of the invention.

### PREFERRED EMBODIMENTS OF THE INVENTION

### First Embodiment

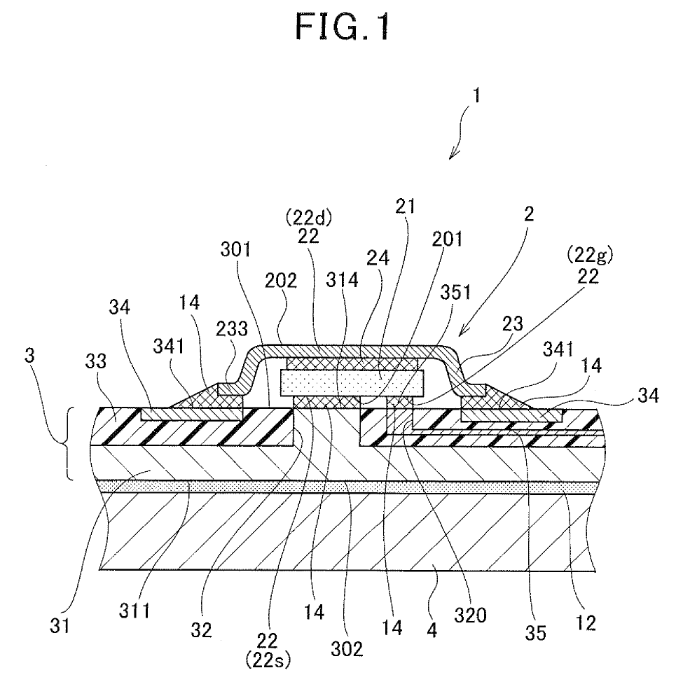

A semiconductor module mounting structure 1 of a first embodiment of the invention is described with reference to FIGS. 1 to 7. As shown in FIGS. 1 to 4, the semiconductor module mounting structure 1 of this embodiment has a structure in which a semiconductor module 2 including therein a semiconductor device 21, and electrodes 22 exposed to both surfaces in the thickness direction thereof is mounted on a wiring substrate 3.

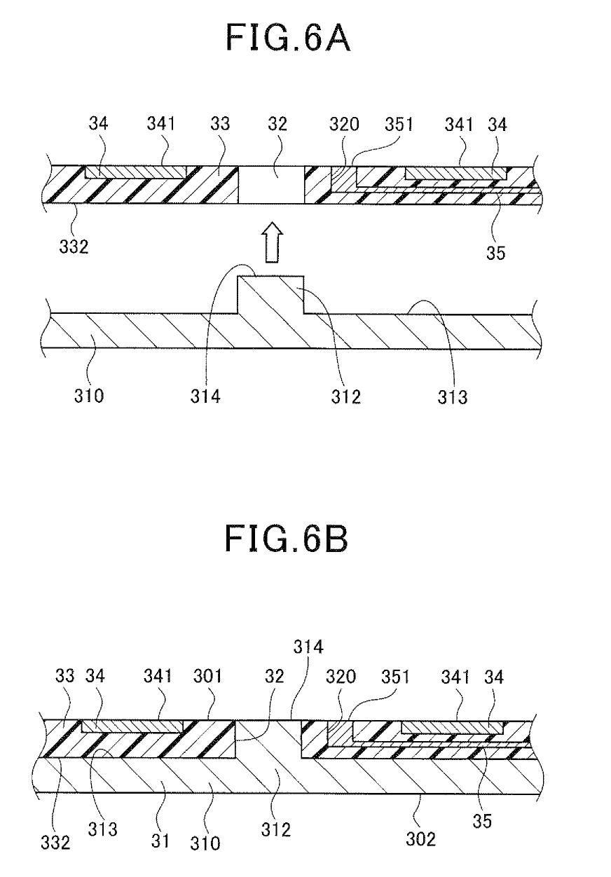

As shown in FIG. 1 and FIG. 6B, the wiring substrate 3 has a structure in which a ground wiring 31 is laid so as to be exposed at least partially to a back surface 302 of the wiring substrate 3 opposite to a front mounting surface 301 of the wiring substrate 3 on which the semiconductor module 2 is mounted. As shown in FIG. 1, an exposed surface 311 of the ground wiring 31 exposed to the back surface 302 is thermally connected to a heat radiating body 4.

The semiconductor module 2 connects the electrode 22s exposed to an opposed surface 201 thereof which is opposed to the wiring substrate 3 to the ground wiring 31 through a through hole 32 formed in the wiring substrate 3. The back surface 302 of the wiring substrate 3 is formed as the exposed surface 311 of the ground wiring 31 in its entirety.

As shown in FIG. 6A, the ground wiring 31 is formed of a conductive plate 310 made of copper or a copper alloy. The conductive plate 310 is formed with a projection 312 at one surface 313 thereof. As shown in FIGS. 6A and 6B, the projection 312 is fitted into the through hole 32 formed in an insulating substrate 33 constituting the wiring substrate 3, the one surface 313 of the conductive plate 310 being joined to a back surface 332 of the insulating substrate 33 to form the wiring substrate 3. The conductive plate 310 constituting the ground wiring 31 has a thickness of from 1 to 2 mm.

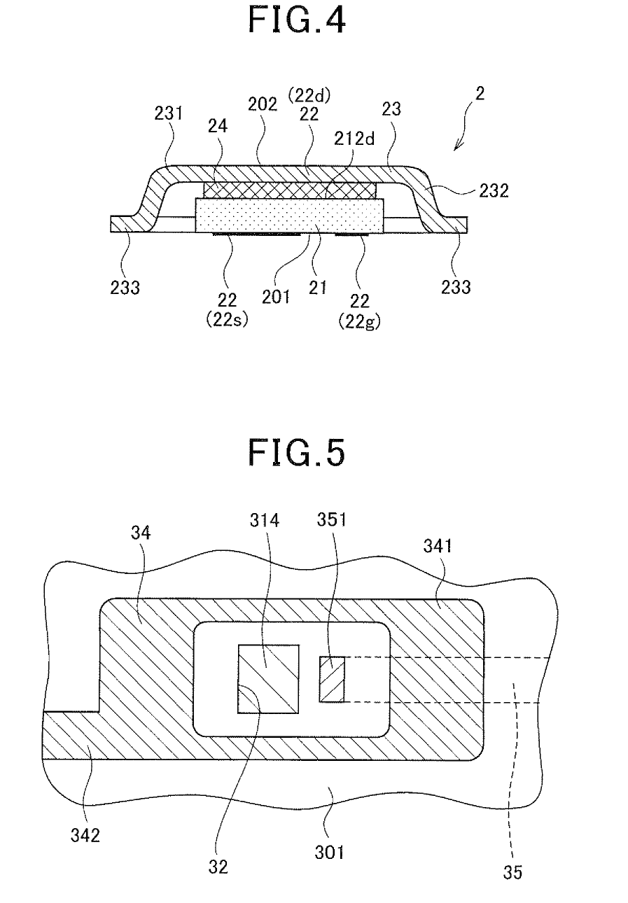

As shown in FIGS. 1 to 4, the electrode 22s exposed to the opposed surface 201 of the semiconductor module 2 is a negative electrode. More specifically, the semiconductor device 21 is a MOSFET, and the electrode 22s exposed to the opposed surface 201 of the semiconductor module 2 is a source terminal of the semiconductor device 21. The electrode 22d exposed to a backside surface 202 opposite to the opposed surface 201 is connected to a drain terminal 212d of the semiconductor device 21. The electrode 22g as a gate terminal of the semiconductor device 21 is also exposed to the opposed surface 201 of the semiconductor device 2. Accordingly, as shown in FIGS. 3 and 4, the semiconductor device 21 integrated in the semiconductor module 2 includes the electrode 22s as the source terminal and the electrode 22g as the gate terminal located on its one surface (the opposed surface 201) in the thickness direction.

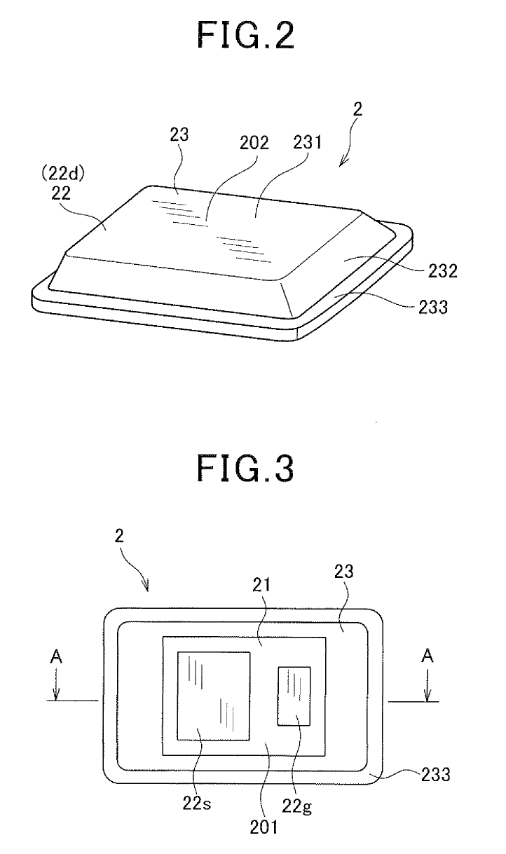

The semiconductor device 21 further includes the drain terminal 212d located on the other surface in the thickness direction. The drain terminal 212d is joined with a conductive member 23 through solder 24, the conductive member 23 serving as the electrode 22d exposed to the backside surface 202 of the semiconductor module 2. The conductive member 23 is formed by squeeze-pressing a plate-like body made of copper or copper alloy. As shown in FIG. 2, the conductive member 23 includes a rectangular back surface portion 231 constituting the backside surface 202 of the semiconductor module 2, a lateral side portion 232 extending obliquely from the entire periphery of the back surface portion 231, and a collar portion 233 extending outside from the end portion of the lateral side portion 232. The semiconductor device 21, conductive member 23, and the solder 24 constitute the semiconductor module 2.

As shown in FIGS. 1, 5 and 6B, the wiring substrate 3 is formed with a first wiring pattern 34 connected to the drain terminal (electrode 22d) at the mounting surface 301 thereof, and a second wiring pattern 35 connected to the gate terminal (electrode 22g) through a through hole 320 formed in the insulating substrate 33 which constitutes the wiring substrate 3. The first and second wiring patterns 34 and 35 may be formed by copper plating.

As shown in FIG. 5, the first wiring pattern 34 includes a drain pad portion 341 formed in a ring shape in the mounting surface 301 of the wiring substrate 3, and a lead portion 342 drawn outside from a part of the drain pad portion 341. As shown in FIGS. 5 and 6B, the second wiring pattern 35 is formed in an inner layer of the insulating substrate 33 to include a gate pad portion 351 exposed at one end thereof to the mounting surface 301 inside the ring-like drain pad portion 341 of the first wiring pattern 34.

To the inside of the drain pad portion 341, also a source pad portion 314 is exposed through the through hole 32 penetrating from the ground wiring 31 to the side of the mounting surface 301. The source pad portion 314, gate pad portion 351, and drain pad portion 341 are joined respectively with the electrode 22s of the source terminal, electrode 22g of the gate terminal, and electrode 22d of the drain terminal by the solder 14, to thereby mount the semiconductor module 2 on the wiring substrate 3.

The electrode 22d of the drain terminal 212d exposed to the backside surface 202 opposite to the opposed surface 201 of the semiconductor module 2 is connected to the non-grounded first wiring pattern 34 formed in the wiring substrate 3 through the conductive member 23. The collar portion 233 of the conductive member 23 is connected at its entire periphery to the first wiring pattern 34 formed on the mounting surface 301 of the wiring substrate 3 by the solder 14.

The wiring substrate 3 is joined to the heat radiating body 4 at the back surface 302 thereof through a heat conductive adhesive 12. The adhesive 12 is a paste-like material made of epoxy binder mixed with metal filler, and has an electrical conductivity. The heat radiating body 4 is made of aluminum or an alloy thereof. The heat radiating body 4 may be tight-fitted to a case of a below-described inverter 5 including the semiconductor module mounting structure 1 of this embodiment, or may be a part of the enclosure.

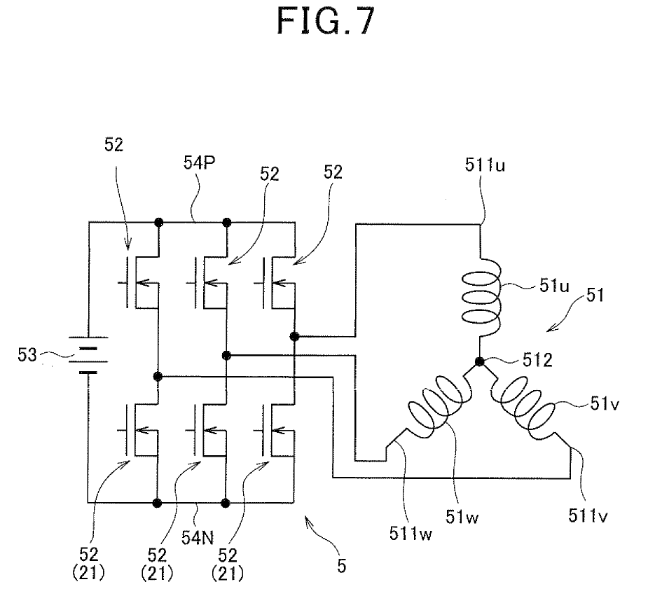

The semiconductor device 21 can be used as a switching element 52 of the inverter 5 for driving a 3-phase brushless motor 51 as shown in FIG. 7.

The inverter 5 includes three parallel arms, each of which is constituted by a pair of switching elements 52 connected in series between a positive line 54P connected to a positive terminal of a DC power supply 53 and a negative line 54N connected to a negative terminal of the DC power supply 53. A wiring connected between the switching element 52 on the high side connected to the positive line 54P and the switching element 52 on the low side connected to the negative line 54N of each of the arms is connected to a corresponding one of a U-phase terminal 511u, a V-phase terminal 511v and a W-phase terminal 511w of the brushless motor 51.

The brushless motor 51 includes three stator windings 51u, 51v and 51w whose one ends are star-connected at a neutral point 512, and whose other ends are connected to the U-phase terminal 511u, V-phase terminal 511v and W-phase terminal 511w, respectively.

At least each of the switching elements 52 on the low side is the semiconductor device 21 of the above described semiconductor module mounting structure 1. Also each of the switching elements 52 on the high side may be the semiconductor device 21 of the semiconductor module mounting structure 1.

Next, the operation and effects of the first embodiment is explained. As explained in the foregoing, the semiconductor module 2 includes the electrodes 22 exposed to both surfaces thereof. The electrode 22s exposed to the opposed surface 201 is connected to the ground wiring 31 which is in thermal contact with the heat radiating body 4 located on the back surface 302 of the wiring substrate 3. Accordingly, the semiconductor module 2 can dissipate heat from the side of the opposed surface 201 through the ground wiring 31 and the heat radiating body 4. In addition, since the wiring substrate 3 is not located on the side of the backside surface 202 opposite to the opposed surface 201, it is possible to dissipate heat into the air directly or through a heat radiating member from the side of the backside surface 202 as well. As explained above, the semiconductor mounting structure 1 of this embodiment enables dissipating heat from both surfaces thereof, to thereby improve heat radiating efficiency.

The back surface 302 of the wiring substrate 3 is constituted by the exposed surface 311 of the ground wiring 31 in its entirety. This makes it possible to dissipate heat from the semiconductor module 2 further efficiently through the ground wiring 31. As shown in FIG. 6A, the ground wiring 31 is constituted by the conductive plate 310 formed with the projection 312 at its one surface 313, and the wiring substrate 3 is formed by inserting the projection 312 into the through hole 32 formed in the insulating substrate 33 and by joining the other surface 313 of the conductive plate 310 to the back surface 332 of the insulating substrate 33. This makes it possible to locate the ground wiring 31 having a large cross-section on the back surface 302 of the wiring substrate 3 with ease, and to provide an electrically conductive means in the through hole 32 with ease.

The electrode 22s exposed to the opposed surface 201 of the semiconductor module 2 is the source terminal, and the electrode 22d exposed to the backside surface 202 is the drain electrode. Accordingly, since the source terminal is connected to the ground wiring 31, electrical stability can be ensured. The wiring substrate 3 is formed with the first wiring pattern 34 connected to the drain terminal (electrode 22d) at the mounting surface 301 thereof, and formed with the second wiring pattern 35 connected to the gate terminal (electrode 22g) through the through hole 320 at the inside of the insulating substrate 33. This makes it possible to increase the wiring density of the wiring substrate 3, to thereby make the wiring substrate 3 compact in size.

In the case where the semiconductor device 21 is used as the switching element 52 on the low side of the inverter 5, particularly in the case where the negative electrode of the semiconductor module 2, that is, the source terminal (electrode 22s) is exposed to the opposed surface 201, it is possible to improve the heat dissipating characteristic of the electrode connected to the negative line 54N of the inverter 5, and also to ground the negative line 54N with ease.

Also, in this case, since the source terminal (negative electrode) can be directly connected to the ground wiring 31, and accordingly it is not necessary to provide any insulating member, which generally has a large thermal resistance, between the ground wiring 31 and the heat radiating body 4, the heat dissipating efficiency can be significantly improved, because the thermal resistance between the ground wiring 31 and the heat radiating body 4 can be significantly reduced.

As explained above, according to this embodiment, there is provided the semiconductor module mounting structure capable of efficiently dissipating heat from both surfaces of the semiconductor device.

### Second Embodiment

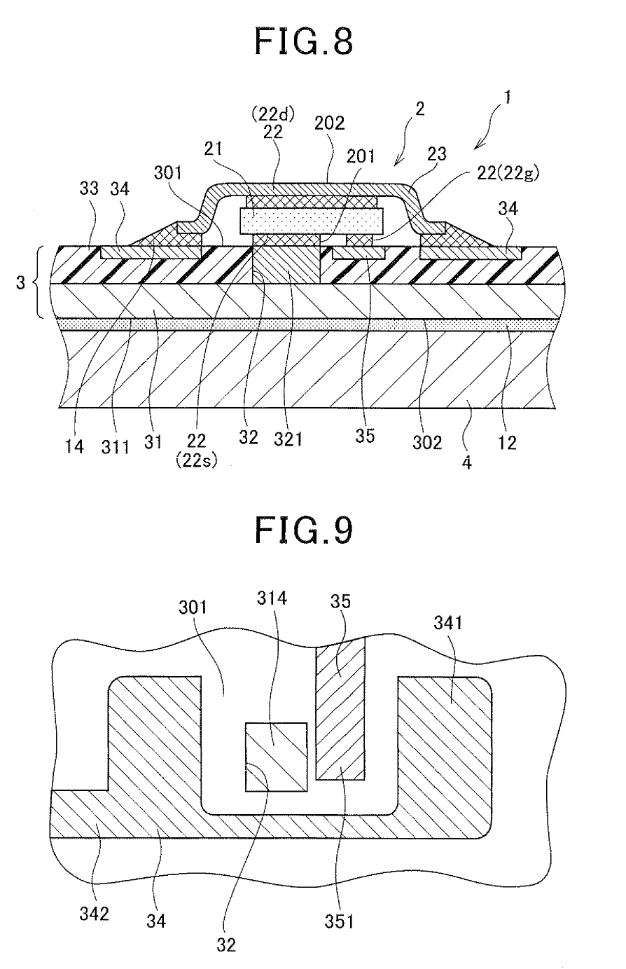

As shown in FIGS. 8 and 9, the second embodiment of the invention is characterized in that the first wiring pattern 34 and the second wiring pattern 35 are formed on the mounting surface 301, and the wiring substrate 3 is formed of a film-like insulating substrate having the through hole 32 formed therein. The wiring substrate 3 is adhered to the surface of the conductive plate 310, and a conductor 321 within the through hole 32 is connected to the conductive plate 310.

The film-like insulating substrate 33 is joined to the conductive plate 310 by a prepreg, and the conductor 321 within the through hole 32 is connected to the conductive plate 310 by solder or conductive paste. The film-like insulating substrate 33 has a thickness of 0.2 to 0.5 mm.

The first wiring pattern 34 connected to the drain terminal (electrode 22d), and the second wiring pattern 35 connected to the gate terminal (electrode 22g) are formed on the mounting surface 301. As shown in FIG. 9, the first wiring pattern 34 includes the drain pad portion 341 formed to have a C-shape surrounding a planar region on three sides. The gate pad portion 351 of the second wiring pattern 35 is formed in this region surrounded by the drain pad portion 341 on three sides, the second wiring pattern 35 being extended in the direction in which the drain pad portion 341 is not formed. In this region, there is formed also the source pad portion 314 exposed to the mounting surface 301. The other components of this embodiment are the same as those of the first embodiment.

Also in this embodiment, the ground wiring 31 having a large cross-section can be easily located on the back surface 302 of the wiring substrate 3. Furthermore, this embodiment provides, in addition to the advantages provided by the first embodiment, the advantage that since it is not necessary for the wiring substrate 3 to be a laminated wiring substrate, the manufacturing process becomes simple.

### Third Embodiment

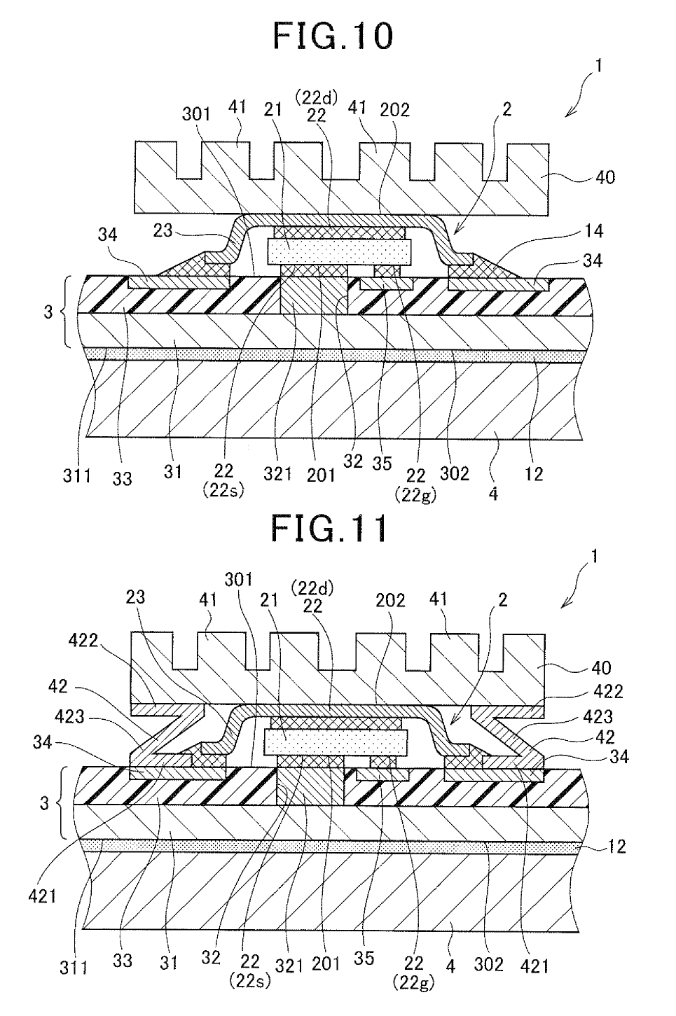

The third embodiment of the invention shown in FIG. 10 is characterized in that the electrode 22d exposed to the back surface 202 of the semiconductor module 2 is disposed so as to be in thermal contact with a backside heat radiating body 40. The backside heat radiating body 40, which is made of aluminum or its alloy, is provided with heat-radiating fins 41 at its surface opposite to its other surface contacting the backside surface 202 of the semiconductor module 2. The other components of this embodiment are the same as those of the second embodiment.

Also according to this embodiment, the semiconductor module mounting structure capable of dissipating heat further efficiently can be obtained, because heat can be dissipated efficiently also from the electrode 22d exposed to the back surface 202 of the semiconductor module 2. The third embodiment provides, in addition to the above advantage, the same advantages as provided by the second embodiment.

### Fourth Embodiment

The fourth embodiment of the invention shown in FIG. 11 is characterized in that a resilient spacer 42 is provided between the mounting surface 301 of the wiring substrate 3 and the backside heat radiating body 40. The resilient spacer 42, which is a spring body elastically deformable in the direction perpendicular to the mounting surface 301, is formed by forming a metal plate made of copper or aluminum in a “Z” shape. That is, the resilient spacer 42 is constituted by a leg portion 421 and a bearing portion 422 located parallel to each other, and a coupling portion 423 coupling the leg portion 421 and bearing portion 422 in a state of being inclined to them.

The leg portion 421 is joined to the first wiring pattern 34 on the mounting surface 301 of the wiring substrate 3, and the bearing portion 422 is abutted on the backside heat radiating body 40. The resilient spacer 42 is disposed between the wiring substrate 3 and the backside heat radiating body 40 in a state of being biased in the direction to extend the distance between them. The other components of this embodiment are the same as those of the third embodiment.

According to this embodiment, since the resilient spacer 42 resiliently ensures space between the mounting surface 301 and the backside heat radiating body 40, it is possible to prevent the semiconductor module 2 from being applied with a large load, while ensuring contact between the backside heat radiating body 40 and the back surface 202 of the semiconductor module 2. The fourth embodiment provides, in addition to the above advantage, the same advantages as provided by the third embodiment.

### Fifth Embodiment

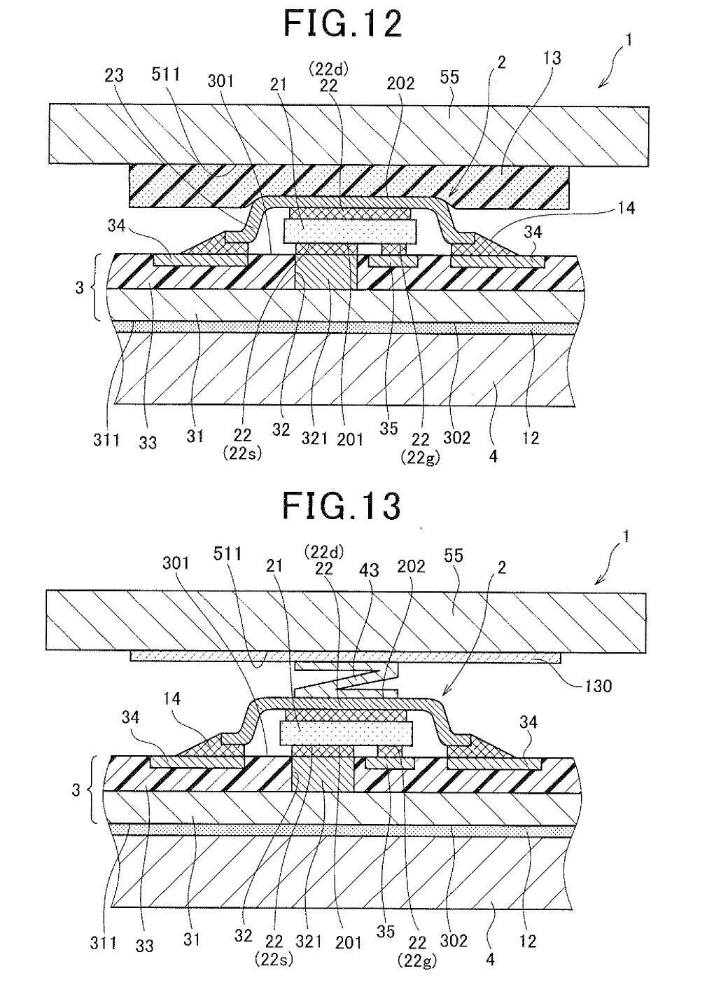

The fifth embodiment of the invention is characterized in that an insulating member 13 is interposed between the back surface 202 of the semiconductor module 2 and an inner surface 551 of the case 55 of the inverter, and the semiconductor module 2 is pressed toward the wiring substrate 3 through the insulating member 13, as shown in FIG. 12. The insulating member 13 is made of a resilient material having a high heat conductivity such as a thin film of silicon. The case 55 is made of metal such as aluminum. The other components of this embodiment are the same as those of the second embodiment.

According to this embodiment, the semiconductor module 2 can be stably held within the case 55 while ensuring electrical insulation between the electrode 22d exposed to the back surface 202 of the semiconductor module 2 and the case 55. The fifth embodiment provides, in addition to the above advantage, the same advantages as provided by the second embodiment.

### Sixth Embodiment

The sixth embodiment of the invention is characterized in that an insulating member 130 and a resilient member 43 are interposed between the back surface 202 of the semiconductor module 2 and the case 55, as shown in FIG. 13. In more detail, the insulating member 130 made of a ceramic plate is closely secured to the inner surface 551 of the case 55, and the resilient member 43 having a “Z”-shaped cross section is interposed between the surface of the insulating member 130 on the side opposite to the inner surface 551 and the back surface 202 of the semiconductor module 2. The resilient member 43 is biased in the direction to extend the distance between the insulating member 130 and the semiconductor module 2. The ceramic plate constituting the insulating member 130 is made of material having a high heat conductivity such as alumina. The resilient member 43 is made of metal such as aluminum or copper. The other components of this embodiment are the same as those of the fifth embodiment.

According to this embodiment, the cushioning action of the resilient member 43 makes it possible to prevent the semiconductor module 2 from being applied with a large load. That is, this embodiment is capable of resiliently holding the semiconductor module 2 within the case 55 by the provision of the resilient member 43, although the insulating member 130 is made of a ceramic plate which is hard to deform. The sixth embodiment provides, in addition to the above advantage, the same advantages as provided by the fifth embodiment.

### Seventh Embodiment

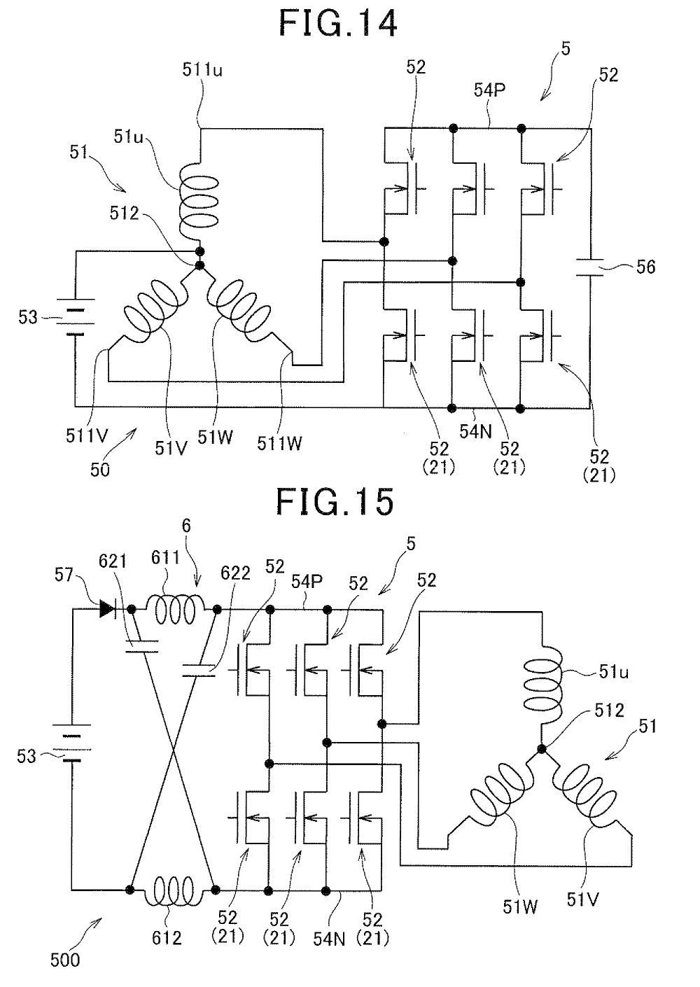

The seventh embodiment is an application of the invention to the switching element 52 of the inverter 5 shown in FIG. 14. The inverter 5 is mounted in a motor drive circuit 50 having a structure which connects the neutral point 512 of the star-connected stator windings 51u, 51v and 51w of the brushless motor 51 to the positive terminal of the DC power supply 53, and connects the negative terminal of the DC power supply 53 to the negative line 54N of the inverter 5. Between the positive line 54P and the negative line 54N, there is connected a capacitor 56 which constitutes a part of a voltage step-up circuit together with one of the stator windings 51u, 51v and 51w of the brushless motor 51. Such an inverter having the above structure is disclosed, for example, in Japanese Patent Application Laid-open No. 10-337047.

At least each of the switching elements 52 on the low side of the inverter 5 is the semiconductor device 21 of the semiconductor module mounting structure 1 of the first to sixth embodiments of the invention. The switching elements 52 on the high side may be also the semiconductor device 21 of the semiconductor module mounting structure 1. The other components of this embodiment are the same as those of the first embodiment.

Since the current flowing in the motor drive circuit 50 is offset to the negative side, the current intensity at the switching elements 52 on the low side is larger than that at the switching elements 52 on the high side. Accordingly, by using the semiconductor module mounting structure 1 for each of the switching elements 52 on the low side, the advantages of the invention can be fully obtained.

### Eighth Embodiment

The eighth embodiment is an application of the invention to the switching element 52 of the inverter 5 shown in FIG. 15. The inverter 5 is mounted in a motor drive circuit 500 including a voltage step-up section 6 located midway to the DC power supply 53. The voltage step-up section 6 has a structure in which a first coil 611 is connected between the positive terminal of the DC power supply 53 and the positive line 54P of the inverter 5, and a second coil 612 is connected between the negative terminal of the DC power supply 53 and the negative line 54N of the inverter 5. Between one terminal of the first coil 611 on the side of the DC power supply 53 and one terminal of the second coil 612 on the side of the inverter 5, a first capacitor 621 is connected, and between the other terminal of the first coil 611 on the side of the inverter 5 and the other terminal of the second coil 612 on the side of the DC power supply 53, a second capacitor 622 is connected. Between the positive terminal of the DC power supply 53 and the first coil 611, a back-current preventing diode 57 is connected.

Such an inverter having the above structure, generally called a “Z-source inverter”, is disclosed in “Maximum Constant Boost Control of the Z-Source Inverter” Shen, M. Wang, J. Joseph, A. Peng, F. Z. Tolbert, L. M. Adams, D. J., CONFERENCE RECORD OF THE IEEE INDUSTRY APPLICATIONS CONFERENCE, IEEE Industrial Application Society, 2004, CONF 39; VOL 1, p. 142-p. 147.

At least each of the switching elements 52 on the low side of the inverter 5 is the semiconductor device 21 of the semiconductor module mounting structure 1 of first to sixth embodiments of the invention. The switching elements 52 on the high side may be also the semiconductor device 21 of the semiconductor module mounting structure 1.

It is desirable that the semiconductor module 2 used in the motor drive circuit 500 is the one described in the third to sixth embodiments in which the semiconductor module 2 is provided with the backside heat radiating body 40 at its back surface 202, or is in thermal contact with the case 55, because, in this embodiment, a large current flows also on the drain terminal side of the semiconductor module 2. The other components of this embodiment are the same as those of the first embodiment.

In the motor drive circuit 500 having the above structure, the DC power supply 53 is short-circuited once by turning on all the switching elements 52 when the voltage step-up section 6 starts voltage step-up operation. At this time, since a large current flows through each of the switching elements 52, the temperature of them is likely to increase significantly. Accordingly, by applying the semiconductor module mounting structure of the invention to the semiconductor module of the switching elements 52 of the inverter 5 mounted in the motor drive circuit 500, the advantages of the invention can be fully obtained.

The semiconductor module mounting structure of the invention is applicable also to a DC-DC converter for supplying electric power to auxiliaries of a vehicle. Although each of the first to eighth embodiments describes an example in which the semiconductor device 21 is an MOSFET, the invention is applicable to a case where the semiconductor device 21 is a bipolar transistor such as an IGBT. In this case, it is desirable that the emitter terminal of the bipolar transistor is exposed to the opposed surface 201 of the semiconductor module 2, and the collector terminal of the bipolar transistor is exposed to the back surface of the semiconductor module 2.

The above explained preferred embodiments are exemplary of the invention of the present application which is described solely by the claims appended below. It should be understood that modifications of the preferred embodiments may be made as would occur to one of skill in the art.

What is claimed is:

1. A semiconductor module mounting structure, comprising:
a semiconductor module including therein a semiconductor device and electrodes exposed to both surfaces thereof in a thickness direction thereof;
a wiring substrate having a mounting surface on which said semiconductor module is mounted; and
a first heat radiating body for dissipating heat from said semiconductor module;
said wiring substrate being formed with a ground wiring such that at least a part of said ground wiring is exposed to a back surface thereof opposite to said mounting surface;
an exposed surface of said ground wiring exposed to said back surface being in thermal contact with said first heat radiating body,
at least one of said electrodes exposed to one of said both surfaces as an opposed surface opposed to said wiring substrate being in electrical contact with said ground wiring through a through hole formed in said wiring substrate.

2. The semiconductor module mounting structure according to claim 1, wherein said electrode exposed to said opposed surface of said semiconductor module is a negative electrode.

3. The semiconductor module mounting structure according to claim 1, wherein an entire back surface of said wiring substrate opposite to said mounting surface is constituted by said exposed surface of said ground wiring.

4. The semiconductor module mounting structure according to claim 1, wherein said wiring substrate is made of an insulating substrate formed with said through hole, and said ground wiring is made of a conductor plate formed with a projection at one surface thereof which is fitted into said through hole formed in said insulating substrate, said one surface of said conductor plate being joined to said back surface of said wiring substrate.

5. The semiconductor module mounting structure according to claim 1, wherein said wiring substrate is constituted by a film-like insulating substrate formed with said through hole and formed with a wiring pattern on one surface thereof as said mounting surface, and by a conductive plate on one surface of which said film-like insulating substrate is adhered, said conductive plate being in electrical connection with a conductor disposed within said through hole.

6. The semiconductor module mounting structure according to claim 1, wherein at least one of said electrodes exposed to the other one of said both surfaces as a back surface of said semiconductor module is electrically connected to a non-grounded wiring pattern formed in said wiring substrate through a conductive material.

7. The semiconductor module mounting structure according to claim 1, wherein said semiconductor device is an FET, said electrode exposed to said opposed surface being a source terminal of said FET, said electrode exposed to said back surface of said semiconductor module being a drain terminal of said FET.

8. The semiconductor module mounting structure according to claim 7, wherein said wiring substrate is formed with a first wiring pattern at said mounting surface thereof and a second wiring pattern at within said wiring substrate, said first wiring pattern being connected to said drain terminal, said second wiring pattern being connected to a gate terminal of said FET through a through hole formed in said wiring substrate.

9. The semiconductor module mounting structure according to claim 7, wherein said wiring substrate is formed with, at said mounting surface thereof, a first wiring pattern connected to said drain terminal and a second wiring pattern connected to a gate terminal of said FET.

10. The semiconductor module mounting structure according to claim 1, further comprising a second heat radiating body provided with heat radiating fins for dissipating heat from said semiconductor module, said electrode exposed to the other one of said both surfaces as a back surface of said semiconductor module being in thermal contact with said second heat radiating body.

11. The semiconductor module mounting structure according to claim 10, wherein a resilient spacer is interposed between said mounting surface of said wiring substrate and said second heat radiating body.

12. The semiconductor module mounting structure according to claim 1, further comprising an insulating member interposed between the other one of said both surfaces as a back surface of said semiconductor module and an inner surface of a case of a device including said semiconductor module mounting structure, said insulating member enabling said semiconductor module to be pressed toward said wiring substrate.

13. The semiconductor module mounting structure according to claim 12, further comprising a resilient member interposed between said back surface of said semiconductor module and said insulating member.

14. The semiconductor module mounting structure according to claim 1, wherein said semiconductor device is usable as a low-side switching element of a power conversion device.

15. The semiconductor module mounting structure according to claim 14, wherein said power conversion device is a DC-DC converter for powering auxiliaries of a vehicle.

16. The semiconductor module mounting structure according to claim 14, wherein said power conversion device is an inverter for driving a brushless motor.

17. The semiconductor module mounting structure according to claim 16, wherein said inverter is mounted in a motor drive circuit having a structure which connects a neutral point of a plurality of star-connected stator windings of said brushless motor to a positive terminal of an external DC power supply, and connects a negative line of said inverter to a negative terminal of said external DC power supply.

18. The semiconductor module mounting structure according to claim 16, wherein said inverter is mounted in a motor drive circuit including a voltage step-up section located midway to an external DC power supply, said voltage step-up section has a structure including a first coil connected between a positive terminal of said external DC power supply and a positive line of said inverter, a second coil connected between a negative terminal of said external DC power supply and a negative line of said inverter, a first capacitor connected between one end of said first coil on a side of said external DC power supply and one end of said second coil on a side of said inverter, and a second capacitor connected between the other end of said first coil on a side of said inverter and the other end of said second coil on a side of said external DC power supply.
